(19) United States
(12) Patent Application Publication
(10) Pub. No.: US 2007/0228895 A1
(43) Pub. Date: Oct. 4, 2007

(54) Method for manufacturing piezoelectric resonator element

(75) Inventor: Sachi Yamamoto, Hino (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 11/695,860

(22) Filed: Apr. 3, 2007

(30) Foreign Application Priority Data
Apr. 4, 2006 (JP) 2006-102910

(51) Int. Cl. H01L 41/00; H01B 13/00

(52) U.S. Cl. 310/365; 216/13

(57) ABSTRACT

A method for manufacturing a piezoelectric resonator element that ensures enough heat dissipation from a piezoelectric substrate, prevents a crack in the piezoelectric substrate, and avoids variation in an etching form when the piezoelectric resonator element is formed by dry etching the piezoelectric substrate is provided. The method includes a first step for placing a quartz crystal substrate 10 on a cooling plate 50 and dry etching the piezoelectric substrate from a main surface on one side that does not contact with the cooling plate 50 along an outline shape portion 20 having a shape along an outline of a tuning-fork crystal resonator element 1 in a cross-section direction of the quartz crystal substrate 10, and a second step for placing a main surface on the one side dry etched in the first step facing the cooling plate 50 and the portion to be cut off contact with the cooling plate, and dry etching a main surface on the other side along the outline shape portion 20 in the cross-section direction of the quartz crystal substrate 10.

### FIELD OF THE INVENTION

The present invention relates to a method for manufacturing a piezoelectric resonator element.

### BACKGROUND TECHNOLOGY

In related art, a piezoelectric resonator element formed from a piezoelectric substrate such as a crystal resonator element is manufactured in a method of machining or wet etching using photolithography to form its outer shape. In recent years, in order to downsize piezoelectric resonator elements and improve productivity, a method for manufacturing a piezoelectric resonator element using wet etching is frequently employed.

However, for example, when a crystal resonator element is manufactured by using wet etching, as an etching speed has anisotropy depending on a direction of a crystal axis, a sidewall inclines and thus an outline shape is not accurately formed. This is a problem that leads to a bad influence to a characteristic for the crystal resonator element. To solve this problem, it is known that etching without anisotropy is possible by forming a quartz crystal substrate using dry etching (refer to Patent Document 1).

For example, a case of manufacturing a conventional tuning-fork crystal resonator element by dry etching a quartz crystal substrate will be explained. FIG. 5 is an explanatory diagram of a manufacturing step illustrating a sectional view of resonating arms of a tuning-fork crystal resonator element. In FIG. 5A, after a metal mask 102 is formed on a portion forming an outline shape of the tuning-fork crystal resonator element including resonating arms 110 on one of main surfaces of a quartz crystal substrate 101, the quartz crystal substrate 101 is placed on a cooling plate 100 and dry etched up to about midway of the substrate thickness.

Next, after a metal mask 103 is also formed on the portion forming the outline shape of the tuning-fork crystal resonator element including the resonating arms 110 on the other main surface of the quartz crystal substrate 101, the surface of the quartz crystal substrate 101 processed in the previous step is placed to contact with the cooling plate 100 as shown in FIG. 5B. Then, as shown in FIG. 5C, dry etching of the quartz crystal substrate 101 is continued to dry etch through the substrate thickness, forming the outline shape of the tuning-fork crystal resonator element as shown in FIG. 5D.

The quartz crystal substrate 101 is thus dry etched from the both sides in order to manufacture the crystal resonator element, however, heat is generated at dry etching. The heat of the quartz crystal substrate 101 is normally dissipated by contacting the quartz crystal substrate 101 with the cooling plate 100.

Patent Document 2 discloses etching performed with a plenty of time in a step of forming an outline shape of a crystal resonator element so as not to leave any protruded portions or the like, and etching up to an appropriate depth in a step of forming a groove of the crystal resonator element.

[Patent Document 1] Japanese Unexamined Patent Publication No. 8-242134 (FIG. 2)

[Patent Document 2] Japanese Patent No. 3729249

### DISCLOSURE OF THE INVENTION

### Problems to be Solved

However, when the other main surface is dry etched (FIGS. 5B, 5C) after the one main surface is dry etched, a contact area of the quartz crystal substrate and the cooling plate is small. Therefore, enough heat dissipation of the quartz crystal substrate cannot be obtained. Because of this, etching temperatures for dry etching from the one main surface and dry etching from the other main surface of the quartz crystal substrate are different. In addition, warpage of the quartz crystal substrate occurs, resulting in a failure in which a shape of the etched surface varies. Further, when heat is accumulated excessively in a quartz crystal substrate, there is a problem in which a crack occurs in the quartz crystal substrate.

The present invention is to solve the problems stated above, and its purpose is to provide a method for manufacturing a piezoelectric resonator element that ensures enough heat dissipation from a piezoelectric substrate, prevents a crack in the piezoelectric substrate, and avoids variation in a shape of etching when the piezoelectric resonator element is formed by dry etching the piezoelectric substrate.

On the other hand, since Patent document 2 does not disclose dry etching, the above-mentioned problems that are peculiar to a dry etching process are not solved.

### MEANS TO SOLVE THE PROBLEM

To solve the problem stated above, the invention is a method for manufacturing a piezoelectric resonator element to form the piezoelectric resonator element by etching a piezoelectric substrate having main surfaces on both front and rear sides and detaching the piezoelectric resonator element from a portion to be cut off, and is characterized by including a first step for placing the piezoelectric substrate on a cooling plate and dry etching the piezoelectric substrate from a main surface on one side that does not contact with the cooling plate along an outline shape portion having a shape along an outline of the piezoelectric resonator element in a cross-section direction of the piezoelectric substrate, and a second step for placing a main surface on the one side dry etched in the first step facing the cooling plate and the portion to be cut off contact with the cooling plate and dry etching a main surface on the other side along the outline shape portion in the cross-section direction of the piezoelectric substrate.

According to this manufacturing method, the outline shape portion having the shape along the outline of the piezoelectric resonator element is dry etched from the one main surface of the piezoelectric substrate so as to form a groove in the first step. Then, in the second step, this one main surface dry etched is placed facing the cooling plate and the outline shape portion is dry etched from the other main surface of the piezoelectric substrate in the cross-section direction. As above, in the second step, the surface of the piezoelectric substrate contacting with the cooling plate is a portion other than the groove formed by etching in the first step, so that a large area including the portion to be cut off can contact with the cooling plate. Heat of the piezoelectric substrate generated by dry etching in the second step is thus adequately dissipated to the cooling plate. According to this, heat does not accumulate in the piezoelectric substrate excessively, and breakage of the piezoelectric substrate does not occur. Further, an etching temperature of dry etching from the one main surface of the piezoelectric substrate and an etching temperature of dry etching from the other main surface become nearly same, reducing variation in forms of etched surfaces.

Furthermore, the second step may be a step to dry etch the outline shape portion to leave a part of the outline shape portion, and the invention may include a third step for removing the outline shape portion by wet etching afterwards.

According to this manufacturing method, employing wet etching whose etching speed is high can reduce processing time and increase production efficiency. Further, wet etching also provides an effect to remove an affected layer having a minute depth formed on the processed surface of the piezoelectric resonator element by dry etching, thereby the piezoelectric resonator element with favorable characteristics can be obtained.

### BRIEF DESCRIPTION OF THE DRAWINGS

FIG. 1 is a block diagram showing a structure of a tuning-fork crystal resonator element formed on a quartz crystal substrate according to a first embodiment. FIG. 1(a) is a schematic plan view while FIG. 1(b) is a sectional view taken along a line A to A in the same figure, FIG. 1(a).

FIG. 2 is a partial plan view schematically showing a shape of a metal mask according to the first embodiment.

FIG. 3 is a partial sectional view schematically showing a manufacturing step of a tuning-fork crystal resonator element in the first embodiment.

FIG. 4 is a partial sectional view schematically showing a manufacturing step of a tuning-fork crystal resonator element in a second embodiment.

FIG. 5 is an explanatory diagram showing a manufacturing step of a tuning-fork crystal resonator element by employing a conventional dry etching.

### REFERENCE NUMERALS

1, 2 . . . tuning-fork crystal resonator element as piezoelectric resonator element, 10 . . . quartz crystal substrate as piezoelectric substrate, 11 . . . resonating arm, 12 . . . base, 14 . . . supporting portion, 15 . . . resonating arm, 20 . . . outline shape portion, 21a, 21b, 23 . . . metal mask, 22, 24 . . . groove, 50 . . . cooling plate

### DESCRIPTION OF PREFERRED EMBODIMENT

Hereinafter, embodiments of the invention will be described with reference to the accompanying drawings. In the embodiments below, methods for manufacturing a tuning-fork crystal resonator element will be described as examples.

### First Embodiment

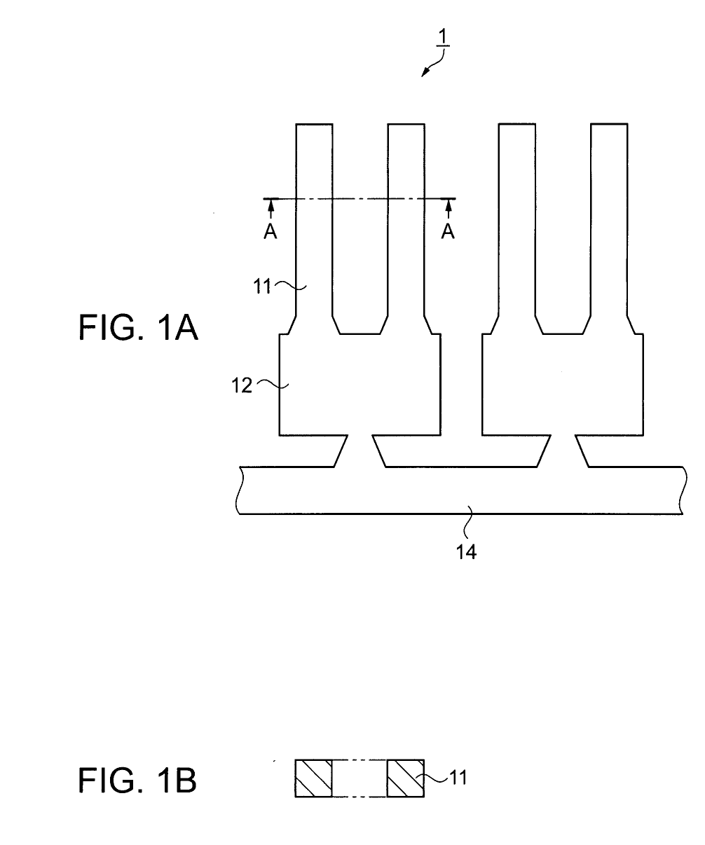

FIG. 1 is a block diagram showing a structure of a tuning-fork crystal resonator element formed on a quartz crystal substrate according to the embodiment. FIG. 1(a) is a schematic plan view while FIG. 1(b) is a sectional view taken along a line A to A in the same figure, FIG. 1(a).

A tuning-fork crystal resonator element 1 is structured by a pair of resonating arms 11 stretched from an end of a base 12. Further, the other end of the base 12 is coupled to a supporting portion 14, and a connected body is formed of a number of tuning-fork crystal resonator elements 1 connected to the supporting portion 14 in the quartz crystal substrate. In addition, a sidewall portion of the tuning-fork crystal resonator element 1 is formed nearly at a right angle to a main surface of the quartz crystal substrate.

Next, a method for manufacturing the tuning-fork crystal resonator element as the above will be described.

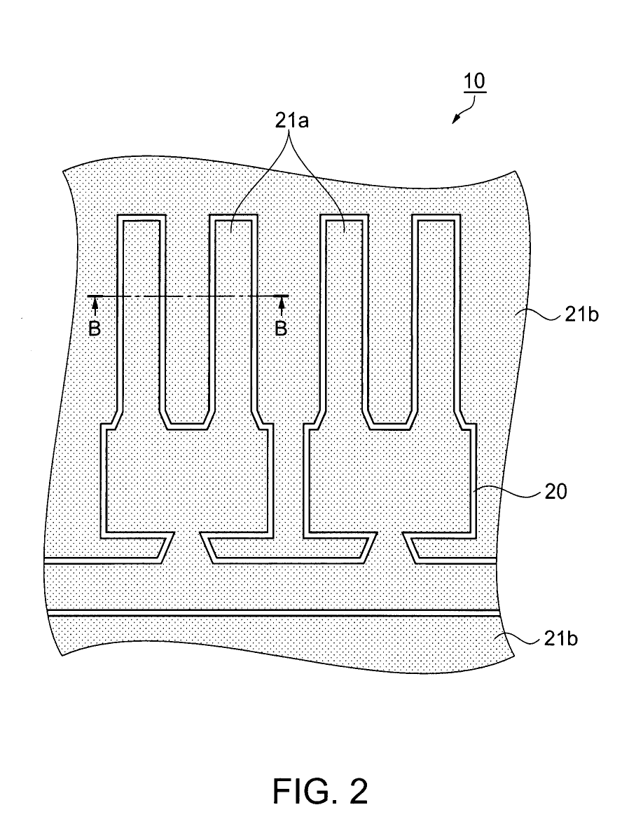

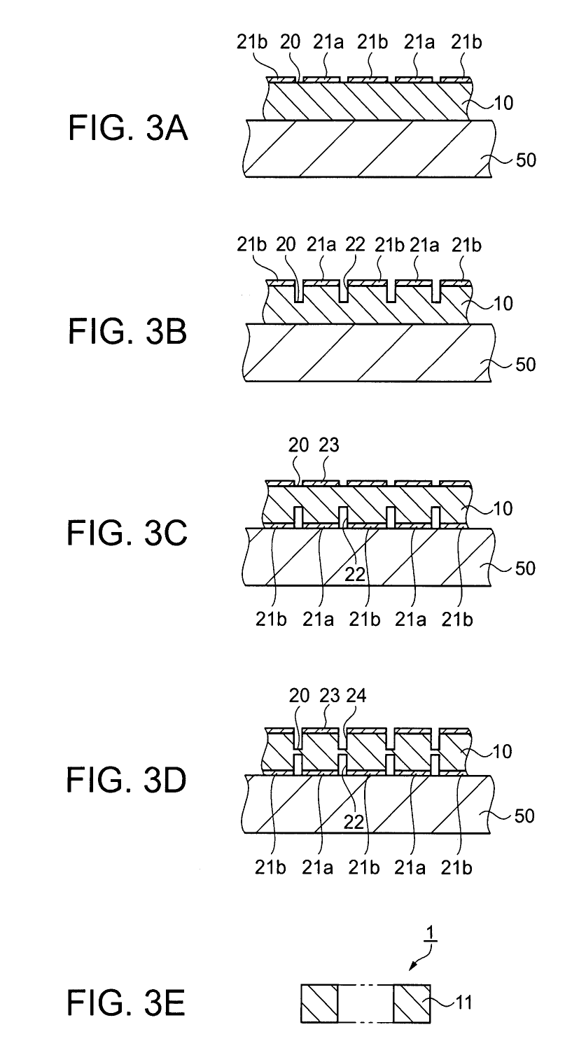

FIG. 2 is a partial plan view schematically showing a form of a metal mask used for dry etching. FIG. 3 schematically shows a partial sectional view taken along a line B-B in FIG. 2, illustrating a manufacturing step of the tuning-fork crystal resonator element.

First, metal masks 21a and 21b made of a material such as Ni as shown in FIG. 2 are formed on one main surface of a quartz crystal substrate 10. These metal masks 21a and 21b are masks having a number of outline shapes of the tuning-fork crystal resonator element 1 and an outline shape of the supporting portion 14, and an outline shape portion 20 that is open in the form of a line along the outline shapes. The metal mask 21a forms a shape of the tuning-fork crystal resonator element while the metal mask 21b forms a shape of a portion to be cut off. Further, the outline shape portion 20 is set to be about from 30 μm to 100 μm wide.

Next, as shown in FIG. 3(a), the quartz crystal substrate 10 having the above-mentioned metal masks 21a and 21b formed are placed on a cooling plate 50 with the surface of the metal mask 21a and 21b up.

Then, as shown in FIG. 3(b), the outline shape portion 20 on the quartz crystal substrate 10 is dry etched in a cross-section direction using the metal masks 21a and 21b as masks. The quartz crystal substrate 10 is dry etched up to about midway of the substrate thickness so as to form a groove 22. At this time, heat generated by the dry etching process is dissipated from the quartz crystal substrate 10 to the cooling plate 50.

In addition, the dry etching process is performed by an oxide film dry etcher that is commonly adopted: a reactive ion etching (RIE) system with a reaction gas such as CHF₃.

Next, after the quartz crystal substrate 10 dry etched is taken out, a metal mask 23 that has a similar pattern to the one in FIG. 2 is formed on the other main surface of the quartz crystal substrate 10. Then, as shown in FIG. 3(c), the one main surface dry etched in the former step is placed to contact with the cooling plate 50.

Subsequently, as shown in FIG. 3(d), the outline shape portion 20 on the quartz crystal substrate 10 is dry etched in the cross-section direction using the metal mask 23 formed on the other main surface of the quartz crystal substrate 10 as a mask, forming a groove 24.

Further, the dry etching process is continued, and the quartz crystal substrate 10 is dry etched through the substrate thickness, detaching the outline of the tuning-fork crystal resonator element 1. At this time, heat generated by the dry etching process is dissipated from the quartz crystal substrate 10 to the cooling plate 50.

Then, after the quartz crystal substrate 10 is taken out, the metal masks 21a, 21b and 23 are removed so as to form the tuning-fork crystal resonator element 1 having resonating arms 11 shown in FIG. 3(e). Thus, a connected body, shown in FIG. 1, formed by a number of tuning-fork crystal resonator elements 1 connected to the supporting portion 14 on the quartz crystal substrate is formed.

As stated above, according to the method for manufacturing the tuning-fork crystal resonator element 1 of the first embodiment, the outline shape portion 20 having a shape along an outline of the tuning-fork crystal resonator element 1 is dry etched from one main surface of the quartz crystal substrate 10 so as to form the groove 22. Then, this one main surface of the quartz crystal substrate 10 dry etched is placed facing the cooling plate 50, and the outline shape portion 20 is dry etched from the other main surface of the quartz crystal substrate 10 in the cross-section direction of the quartz crystal substrate 10, forming the groove 24. As above, in the step to form the groove 24, the surface of the quartz crystal substrate 10 contacting with the cooling plate 50 is a portion other than the groove 22 formed by etching in the former step, so that a large area including the portion to be cut off can contact with the cooling plate 50. Heat of the quartz crystal substrate 10 generated by dry etching is thus adequately dissipated to the cooling plate 50.

Because of this, heat does not accumulate excessively, resulting in no occurrence of breakage of the quartz crystal substrate 10. Then, an etching temperature of dry etching from the one main surface of the quartz crystal substrate and an etching temperature dry etching from the other main surface become nearly same, reducing variations in shapes of etched surfaces. Further, since the outline of the tuning-fork crystal resonator element 1 is formed by dry etching, a sidewall portion is not inclined and formed at a nearly right angle to the main surface of the quartz crystal substrate 10 unlike a case of forming by wet etching.

### Second Embodiment

Next, as a second embodiment, an embodiment using dry etching and wet etching for manufacturing a tuning-fork crystal resonator element will be explained. In the embodiment, the same steps that are explained in the first embodiment are performed until the halfway of the manufacturing steps. Therefore, steps afterwards are explained with reference to the drawings.

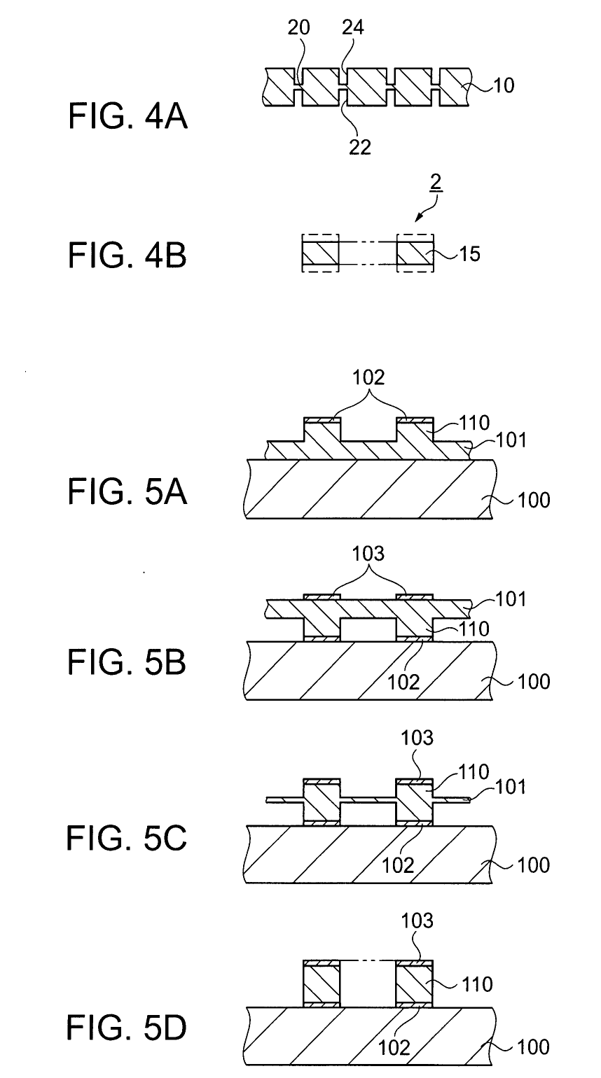

FIG. 4 is a partial sectional view schematically showing a manufacturing step of the tuning-fork crystal resonator element. This sectional view corresponds to a sectional view taken along the line B-B in FIG. 2 as the same as the one explained in the first embodiment.

First, the steps shown in FIG. 3(a) to FIG. 3(c) explained in the first embodiment are performed. Then, as shown in FIG. 3(d), dry etching is performed so as to leave a part of the outline shape portion 20 of the quartz crystal substrate 10.

Then, after the quartz crystal substrate 10 is taken out, as shown in FIG. 4(a), the metal masks 21a, 21b, and 23 are removed. Afterwards, the quartz crystal substrate 10 is wet etched using an etchant such as hydrofluoric acid and ammonium fluoride, removing the outline shape portion 20. In this way, an outline of a tuning-fork crystal resonator element 2 is detached. At this time, a main surface and a sectional surface of the quartz crystal substrate 10 are etched. However, since an etching rate of the main surface is larger than that of the sectional surface, etching is performed so that the crystal 10 can be reduced in thickness. Therefore, resonating arms 15 also have a form in which their thickness are reduced as shown in FIG. 4(b).

As above, a connected body formed by a number of tuning-fork crystal resonator elements 2 connected to a supporting portion is formed on the quartz crystal substrate 10.

In addition, in the embodiment stated above, a whole of the quartz crystal substrate 10 is etched in the wet etching process. However, after a photoresist film is formed at least on the tuning-fork crystal resonator element 2 and the supporting portion, the other portions may be wet etched.

According to the method for manufacturing the tuning-fork crystal resonator element 2 of the embodiment above, employing wet etching whose etching speed is high in addition to the effect of the first embodiment can reduce processing time and increase production efficiency. Further, wet etching also provides an effect to remove an affected layer having a minute depth formed on the processed surface of the tuning-fork crystal resonator element 2 by dry etching, thereby the tuning-fork crystal resonator element 2 with favorable characteristics can be obtained.

In the embodiment, the quartz crystal substrate is placed on the cooling plate and processed. However, the quartz crystal substrate can be placed on a cooling plate in which a fixing sheet to fix the quartz crystal substrate is set.

Further, a tuning-fork crystal resonator element is exemplified as a crystal resonator element in this embodiment. However, it can be used not only for a tuning-fork crystal resonator element, but also applicable to crystal resonators called such as a double-ended tuning-fork resonator element, an H-shaped crystal resonator element, a double T-shaped crystal resonator element, even more, an AT-cut crystal resonator element.

Furthermore, in the embodiments, a quartz crystal substrate is exemplified as a piezoelectric substrate. However, it is applicable to a piezoelectric substrate such as lithium tantalate (LiTaO₃) or lithium niobate (LiNbO₅) other than the quartz crystal substrate.

The entire disclosure of Japanese Patent Application No. 2006-102910, filed Apr. 4, 2006 is expressly incorporated by reference herein.

1. A method for manufacturing a piezoelectric resonator element to form the piezoelectric resonator element by etching a piezoelectric substrate having a main surfaces on both front and rear sides to and detaching the piezoelectric resonator element from a portion to be cut off, comprising:
a first step for placing the piezoelectric substrate on a cooling plate and dry etching the piezoelectric substrate from a main surface on one side that does not contact with the cooling plate along an outline shape portion having a shape along an outline of the piezoelectric resonator element in a cross-section direction of the piezoelectric substrate; and
a second step for placing a main surface on the one side dry etched in the first step facing the cooling plate to and the portion to be cut off contact with the cooling plate, and dry etching a main surface on the other side along the outline shape portion in the cross-section direction of the piezoelectric substrate.

2. The method for manufacturing a piezoelectric resonator element according to claim 1, wherein the second step is a step to dry etch the outline shape portion to leave a part of the outline shape portion, and including a third step for removing the outline shape portion by wet etching afterwards.
